(19) United States
(12) Patent Application Publication
(10) Pub. No.: US 2024/0028809 A1
(43) Pub. Date: Jan. 25, 2024

(54) INTEGRATED CIRCUIT DESIGN, CONTEXTUAL CELLS, DESIGN MIGRATION, AND ASSOCIATED METHODS

(71) Applicant: Silicon Technologies, Inc., Midvale, UT (US)

(72) Inventors: Thomas L. Wolf, Midvale, UT (US); Kent F. Smith, Holladay, UT (US); Tracy L. Johancsik, Murray, UT (US); Alec S. Adair, Midvale, UT (US); Kyler C. Fillerup, Orem, UT (US); Stuart T. Anderson, Midvale, UT (US); Thomas G. Wolf, Bloomington, IN (US)

(21) Appl. No.: 18/356,484

(22) Filed: Jul. 21, 2023

Related U.S. Application Data
(60) Provisional application No. 63/369,059, filed on Jul. 21, 2022.

(51) Int. Cl. G06F 30/392; G06F 30/32

(52) U.S. Cl. CPC G06F 30/392; G06F 30/32

(57) ABSTRACT

Methods are disclosed. A method may include a method of generating an integrated circuit design. The method of generating an integrated circuit design may include generating a contextual cell including a super-master and defining at least one sub-master, the at least one sub-master derived from parameterized values and a context of an instance of the super-master.

### CROSS-REFERENCE TO RELATED APPLICATION

This application claims the benefit of the filing date of U.S. Provisional Patent Application Ser. No. 63/369,059, filed Jul. 21, 2022, for “Integrated-Circuit Design Using Cell-Based Techniques, and Associated Devices and Systems,” the disclosure of which is hereby incorporated herein in its entirety by this reference.

### TECHNICAL FIELD

This disclosure relates generally to integrated-circuit design, and more specifically, to integrated circuit design using cell-based techniques. Additionally, this disclosure relates generally to the field of semiconductor devices and integrated circuits. Additionally, this disclosure relates generally to characterizing circuits. Further, this disclosure relates generally to contextual cells. Additionally, this disclosure relates generally to generating a layout from a parameterized cell. Moreover, this disclosure relates to design migration. Related methods, devices, and systems are also disclosed.

### BACKGROUND

Integrated-circuit (IC) cells include circuit elements and connections therebetween. Integrated-circuit cells can be used as building blocks in the design of a wide variety of integrated-circuit devices. Conventional cells are static, meaning each copy of a cell is the same.

Very large-scale integration (VLSI) technology devices are continuing to scale to smaller feature sizes. The scaling of device feature sizes enables designers to create larger application specific integrated circuits (ASICs) in smaller die areas with faster operating speeds and lower power consumption. As feature size decreases, there is a need to migrate existing circuit designs into smaller process geometries to take advantage of the power and area savings as well as the performance enhancements. The process of design migration is manual and labor intensive.

IC designers often write human-readable descriptions of functionality and specifications of a circuit, e.g., data sheets.

Analog circuit layout tools do not have the ability to migrate designs across technologies and do not maintain the same topological structure as individual transistors in a design are modified.

### BRIEF DESCRIPTION OF THE DRAWINGS

FIG. 1 is a functional block diagram illustrating an example cell, according to various embodiments of the disclosure.

FIG. 2 is a functional block diagram illustrating an example hierarchy of cells, according to various embodiments of the disclosure.

FIG. 3 is a functional block diagram illustrating a super-master and sub-masters of a cell, according to various embodiments of the disclosure.

FIG. 4 is a functional block diagram illustrating two cells, according to various embodiments of the disclosure.

FIG. 5 is a functional block diagram illustrating an example hierarchy, according to various embodiments of the disclosure.

FIG. 6 is a functional block diagram illustrating another example hierarchy, according to various embodiments of the disclosure.

FIG. 7 is a functional block diagram illustrating yet another example hierarchy, according to various embodiments of the disclosure.

FIGS. 8A and 8B collectively illustrate a flowchart of an example method, in accordance with various embodiments of the disclosure.

FIG. 9 is a functional block diagram of an example system, according to various embodiments of the disclosure.

FIG. 10 is a representation of an example FinFET layout of an inverter with guard rings generated from a layout without guard rings.

### DETAILED DESCRIPTION

Detailed descriptions of the preferred embodiment are provided herein. It is to be understood, however, that the present invention may be embodied in various forms. Therefore, specific details disclosed herein are not to be interpreted as limiting, but rather as a basis for the claims and as a representative basis for teaching one skilled in the art to employ the present invention in virtually any appropriately detailed system, structure or manner.

Cells may be used in integrated-circuit design to save time and/or improve designs, e.g., by allowing a designer (either manually or through automation scripts) to replicate copies of a cell in multiple locations within a design and/or within different designs.

In the present disclosure, the term “session” may refer to the runtime environment in which an application used for the development of integrated circuits (e.g., an integrated-circuit-design application) is run. A session is usually initiated when an integrated-circuit-design application starts up and is maintained through the runtime of the application. When the integrated-circuit-design application is closed the session is destroyed and only what has been written to a storage medium (e.g., a disk) will remain persistent between one session and another.

In the present disclosure, the term “cell” may refer to a unit that is a component part of an integrated circuit. A cell may be a container for various models (e.g., models of circuit elements, e.g., resistors, capacitors, and transistors), data structures, shapes, annotations, and even references to other cells. Some cells may be relatively simple, e.g., containing one element, or being empty of data. Other cells may be relatively complex, e.g., containing the entirety of a billion-transistor processor.

In the present disclosure, the term “instance” may refer to a structure within a cell that defines a reference to another cell. A reference to a cell from another cell may define a relationship, e.g., a parent cell/sub-cell relationship. An instance may store information beyond just a reference such as how the sub-cell is used, its physical location, and/or other properties of the cell. For example, a cell defining an inverter circuit may have two instances, a p-type-transistor instance and an n-type-transistor instance. Each of the p-type-transistor instance and the n-type-transistor instance may define a relationship with the other and/or a relative location within the cell.

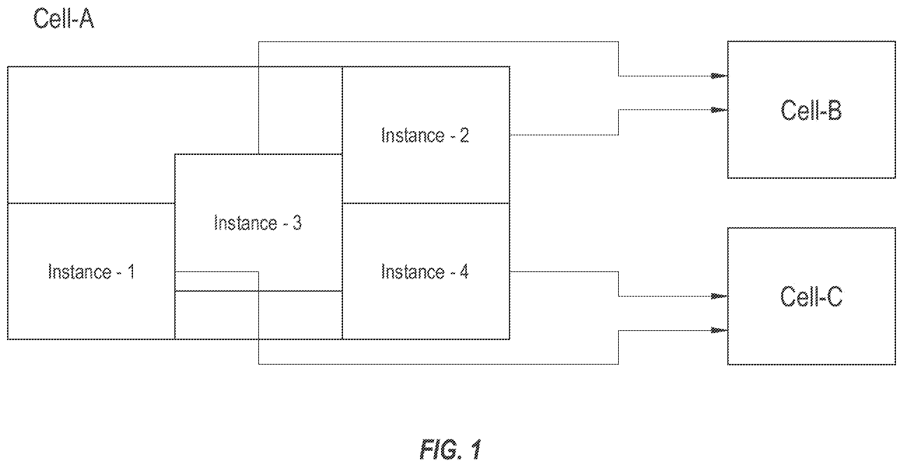

FIG. 1 is a functional block diagram illustrating an example Cell-A according to various embodiments of the disclosure. Cell-A includes instances that reference Cell-B and Cell-C.

In the present disclosure, the term “hierarchy” may refer to relationships between cells. For example, cells may define relationships to other cells using a hierarchy structure. For example, Cell-B and Cell-C may be used as instances in Cell-A (e.g., as illustrated in FIG. 1), thus Cell-B and Cell-C may both be at level 1 in Cell-A's hierarchy.

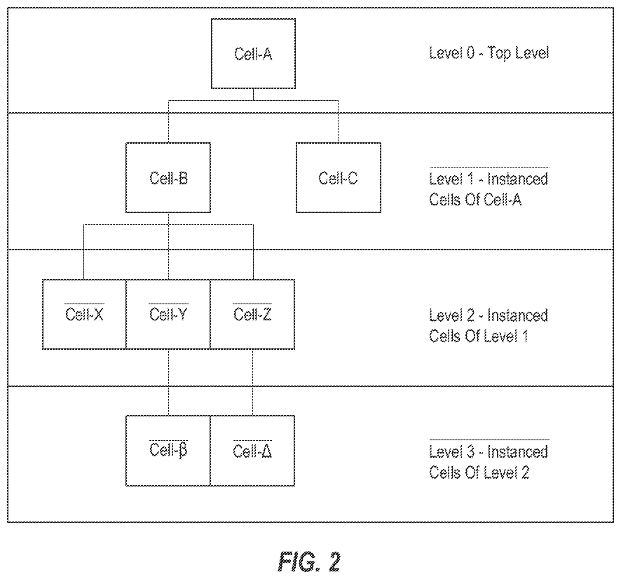

FIG. 2 is a functional block diagram illustrating an example hierarchy of cells according to various embodiments of the disclosure. Cell-A includes one or more instances that reference Cell-B and one or more instances that reference Cell-C. Cell-B includes one or more instances that reference each of Cell-X, Cell-Y, and Cell-Z respectively. Cell-Y includes one or more instances that reference Cell-β. Cell-Z includes one or more instances that reference Cell-A.

A static cell may be defined by internal structures, shapes, and/or instances referencing other cells. A static cell may be stored on a hard disk and may be persistent between sessions. A static cell may not be adaptive to the unique parameters and contexts in which the cell is used as an instance inside another cell, meaning one reference to a static cell will be the exact same as another reference to the same cell.

In contrast, a parameterized cell may be dynamic, e.g., not exclusively defined not by its internal structures, shapes, and/or instances, but also defined by generation software (e.g., a structure generator) attached to the cell and one or more parameters. For example, a user may define parameters which may be used as input by a structure generator. Instead of storing the cell's internal structures, shapes, and/or instances statically during the creation of the cell, the structure generator may create a new variant of the cell (referred to as the sub-master) and store it within a session's memory whenever a unique set of parameters are used in an instance of the base cell. Meaning one reference to a parameterized cell could be different in structure than another reference to the same parameterized cell, so long as the references have different values to their instance's parameters.

In the present disclosure, the term “super-master” may refer to a component of a contextual cell that defines internal structures, shapes, and/or instances or a cell. The super-master may include a definition or specification of the contextual cell. The super-master may be stored on the disk (i.e., may be persistent between sessions). The super-master may be used similarly to a static cell. However, if a cell including a super-master is used as an instance in another cell, the super-master instead calls/uses the structure generator attached to the parameterized cell and creates (or accesses if it has already been created in a session) a unique variant of the parameterized cell defined by a set of parameters, referred to as a sub-master.

In the present disclosure, the term “sub-master” is a unique variant of the parameterized cell defined by a set of parameter's values. When a contextual cell is used as reference for an instance in a cell, the instance will reference the sub-master.

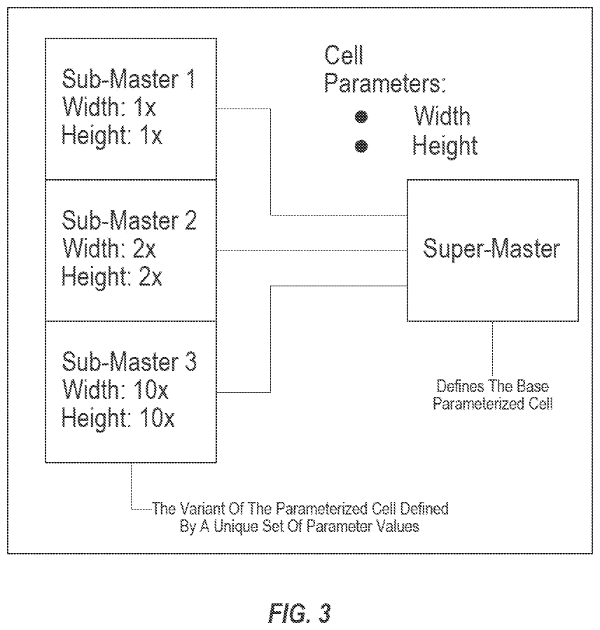

FIG. 3 is a functional block diagram illustrating a super-master and sub-masters according to various embodiments of the disclosure. In particular, FIG. 3 illustrates a cell including a super-master and three sub-masters each with different parameters. The example illustrated in FIG. 3 uses example parameters width and height, but the parameters could be anything defined when the parameterized cell is implemented.

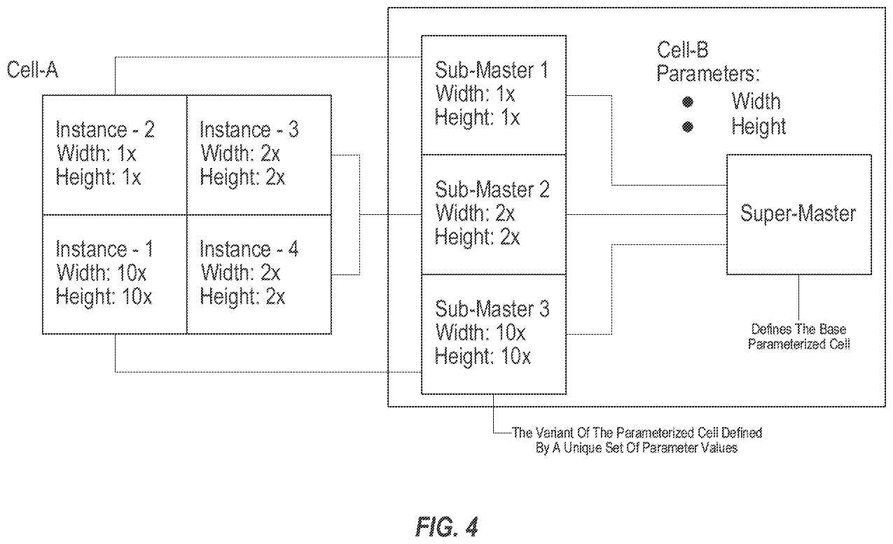

FIG. 4 is a functional block diagram illustrating two cells according to various embodiments of the disclosure. In particular, FIG. 4 illustrates Cell-B including a super-master and three sub-masters and Cell-A including four instances of respective sub-masters.

Parameterized cells may be defined by a structure generator which may generate internal structures, shapes, and/or sub-cells, based on parameters. Parameterized cells may store their structure generator and their abstract representation on the hard disk (e.g., the structure generator and/or abstract representations of parameterized cells may be persistent), while the sub-masters resulting from the structure generators of the parameterized cell are stored in memory (e.g., sub-masters may not persist between sessions). A parameterized cell (or a structure generator thereof) may regenerate its sub-masters stored in memory when the sub-masters is first accessed in a session. Values of parameters may be defined by equivalent parameters set on the instance referencing the parameterized cell. This allows for an instance's reference to be internally manipulated without affecting other references to the same parameterized cell.

Parameterized cells may use structure generators to construct internal structures, shapes, and/or instances based on the respective super-master and based on the unique parameters of a sub-master. This gives an end user the ability to manipulate an instantiation of parameterized cells.

However, even though a user can manipulate instances of parameterized cells, data access may be limited. For example, a parameterized cell's generation software may only be able to access the given parameter's values, the parameterized cell itself, and any instances it references below itself in the hierarchy.

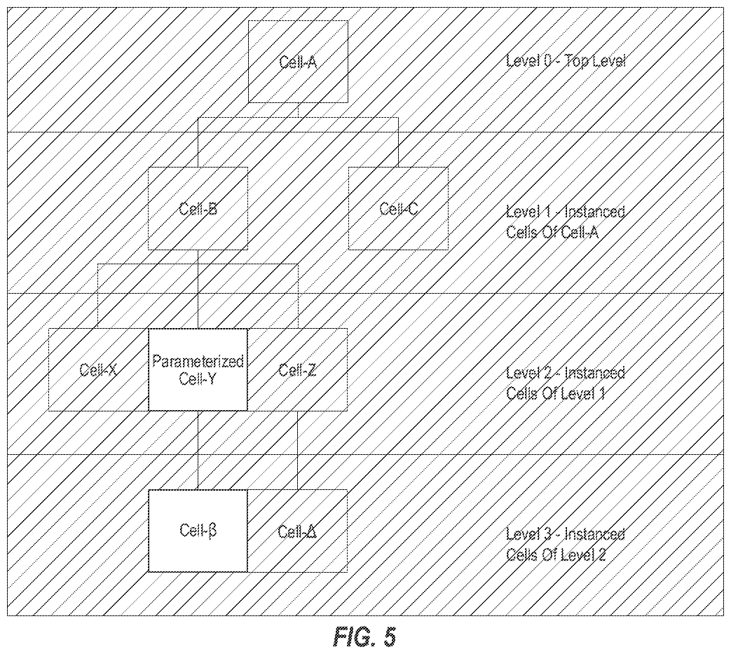

FIG. 5 is a functional block diagram illustrating an example hierarchy according to various embodiments of the disclosure. According to the example hierarchy of FIG. 5, parameterized Cell-Y has access to: Cell-Y, parameters of Cell-Y, Cell-β, and parameters of Cell-β but not to parameters of any of the other cells of FIG. 5.

Contextual cells, like parameterized cells, may be defined, at least in part, by parameters. Additionally, like parameterized cells, contextual cells may include structure generators to generate the internal structures, shapes, and/or instances of the contextual cells in a session and for each instance of each contextual cell. Additionally, contextual cells may use the super-master and sub-master architecture described above with regard to parameterized cells. Additionally, contextual cells may include an additional structure—the instance-context structure. The instance-context structure provides a medium to pass data between the cell the instance is contained within and the generator deriving the structures of the sub-master referenced by the instance.

Contextual cells may allow for greater data access and/or manipulation for the structure generators attached to a contextual cell than is possible using parameterized cells. Because structure generators of contextual cells have access to other cells, contextual cells may allow for instances of the contextual cells to be generated dynamically, e.g., based at least in part on their surroundings. For example, contextual cells may have access (e.g., read access) to all cells of the same hierarchical level and/or to all cells of a lower hierarchical level.

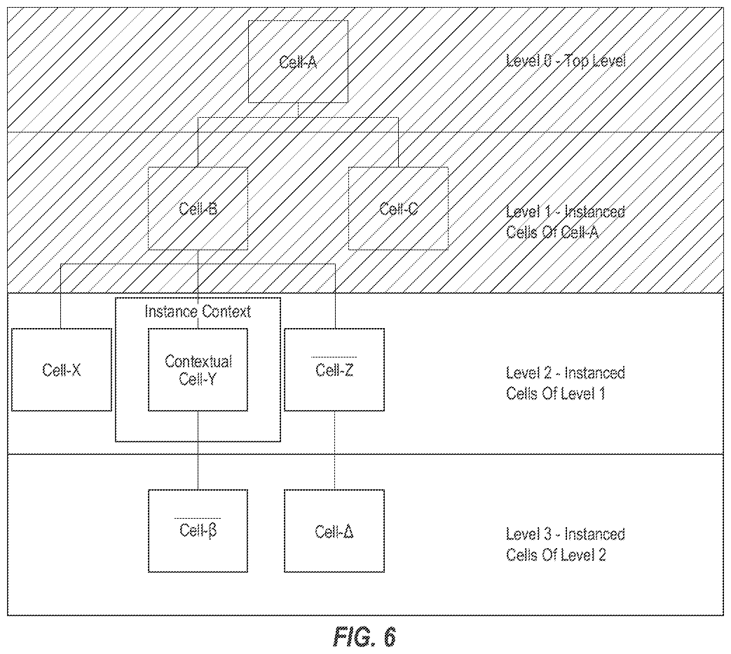

FIG. 6 is a functional block diagram illustrating an example hierarchy according to various embodiments of the disclosure. According to the example hierarchy of FIG. 6, contextual Cell-Y has read access to cells of the same level (e.g., Cell-X and Cell-Z) and to cells of lower levels (e.g., Cell-β and Cell-Δ).

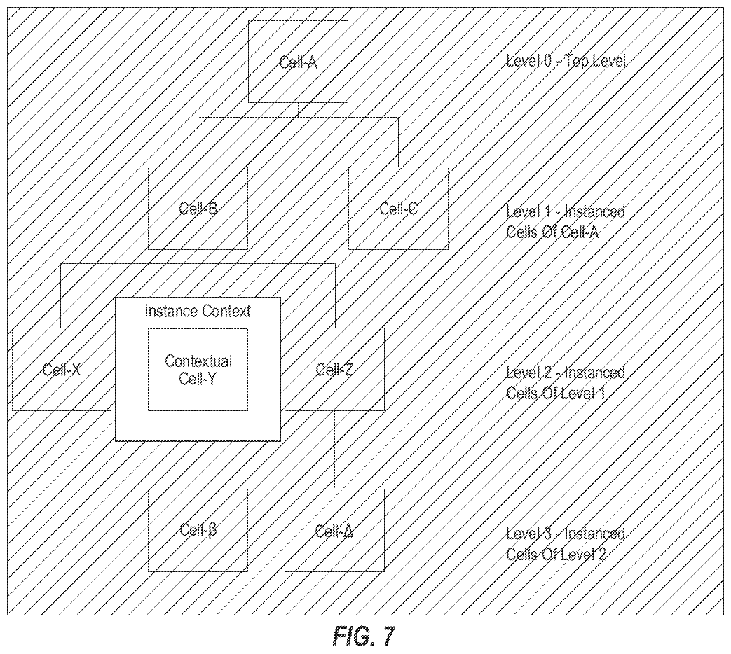

FIG. 7 is a functional block diagram illustrating an example hierarchy according to various embodiments of the disclosure. According to the example hierarchy of FIG. H, contextual Cell-Y has write access to contextual Cell-Y. FIG. 7, compared with FIG. 6, illustrates the differences in the read/write accessibility of the contextual cell's generators.

With read access to cells of the same and/or lower hierarchal levels, a structure generator of a contextual cell may be able to observe internal structures, shapes, and/or instances (collectively or individually referred to herein as “components”) of other cells including, e.g., proximate cells. The structure generator may be able to generate internal structures, shapes, and/or instances of the contextual cell based at least in part on the internal structures, shapes, and/or instances of the other cells.

For example, in a session, a user may place a first instance of a contextual cell, within a larger cell of a design. A structure generator of the contextual cell may observe internal structures, shapes, and/or instances of other cells including cells proximate to and/or closest to the first instance.

Continuing the example, in the same session, the user may place a second instance of the contextual cell within the larger cell of the design. The structure generator of the contextual cell may observe internal structures, shapes, and/or instances of other cells including cells proximate to and/or closest to the second instance. The structure generator may generate the second instance based at least in part on the internal structures, shapes, and/or instances of the other cells. Because the second instance is placed at a location that is different from the first instance, the second instance may reference a different sub-master from the first instance.

Thus, some embodiments include contextual cells which may be dynamic integrated-circuit-cell structures which, when used as a component of another cell, may be reactive to the physical context of its surrounding area. For example, a contextual transistor-layout cell may be placed next to a power rail. The transistor's source connection shares the same net as the power rail. When the contextual transistor cell is placed near the power rail, the transistor's source connection is connected to the power rail (e.g., by the integrated-circuit-design application and/or structure generators of the contextual cell). Later, if the contextual transistor is moved (or other elements, e.g., the power rail is moved), the connection to the power rail may be adjusted as well (e.g., by the integrated-circuit-design application and/or structure generators of the contextual cell).

Some embodiments may be related and/or enable the spatially aware creation of non-functional physical structures, often referred to as fill structures, within a sub-master referenced by an instance of a contextual cell. With spatially aware creation of these structures, cells may be enabled for more performative and uniform composition when an area of surrounding structures are also taken into consideration.

An example of an embodiment's purpose with more functional physical structures may be the evaluation of an instance's need, and creation thereof, of additional body connections to a device's substrate based on the surrounding density and distance to other such connections.

An additional example of an embodiment's purpose with functional physical structures may be the contextual cell's evaluation of physical connection properties, such as the current capacity of a connected metal trace. Once a connection's attributes are evaluated, such as the current capacity, the contextual cell's generators may be able to adjust its own internal structures to match the attributes of the external connections.

A non-physical example of an embodiment's purpose could be an annotation block within a schematic, or another abstracted form, in which the contextual cell's generators could be assigned external structures and produce formatted annotations based on attributes of those external structures. This may enable end-users to create dynamic annotations that adapt to changes in a design, instead of requiring manual updates by the end-user with every change.

Using contextual cells may reduce the time spent by a designer by reducing support structures that need to be manually placed and updated as the design is implemented. This may reduce potential errors by the contextual cell changing as its surroundings change as defined by a particular standard or set of rules. Contextual cells may also allow for contextual validation, such as spacing limitations. Some embodiments relate to migration (e.g., design migration). More specifically, some embodiments may relate to migration of analog integrated circuits (e.g., schematics and/or layouts) from one characteristic value to another characteristic value, such as from one process geometry (e.g., a source technology or a reference technology) to another process geometry (e.g., a target technology or a destination technology). Some embodiments may use cell sets and/or may use transconductance by drain current (“gm/Id”) as a metric in migration.

One aspect of one or more embodiments is directed to characterizing the source technology using a pre-existing cell set for a given process (e.g., the process of the source design) through the gm/Id design methodology. Each single transistor in the cell set is simulated across different biasing regions. For each bias region physical parameters of the transistor are stored. Some of these parameters may include, for example, the gate to source capacitance (Cgs) of the transistor, the transconductance (gm) of the transistor, and the drain to source current (Ids) of the transistor.

Migrating the source design includes characterizing parameters such as: transconductance of each device (e.g., transistor) in the design, drain to source currents of each device (e.g., transistor) in the design, the intrinsic capacitances of each device (e.g., transistor) in the design, and biasing voltages of each attribute in the device (i.e., the characterizing parameters may vary based on the voltage the transistor is biased at).

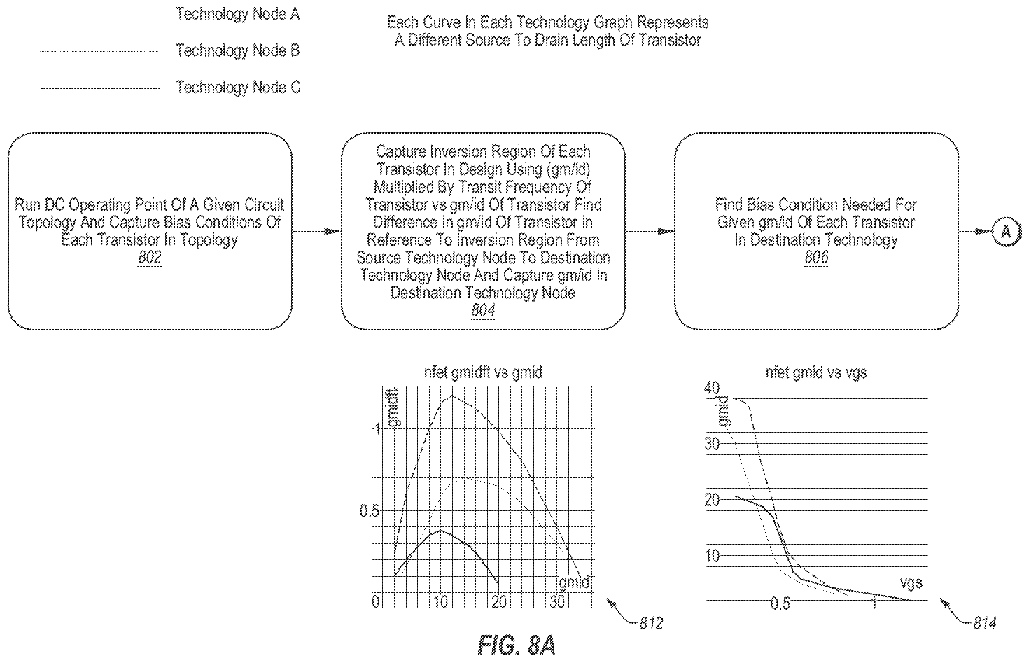

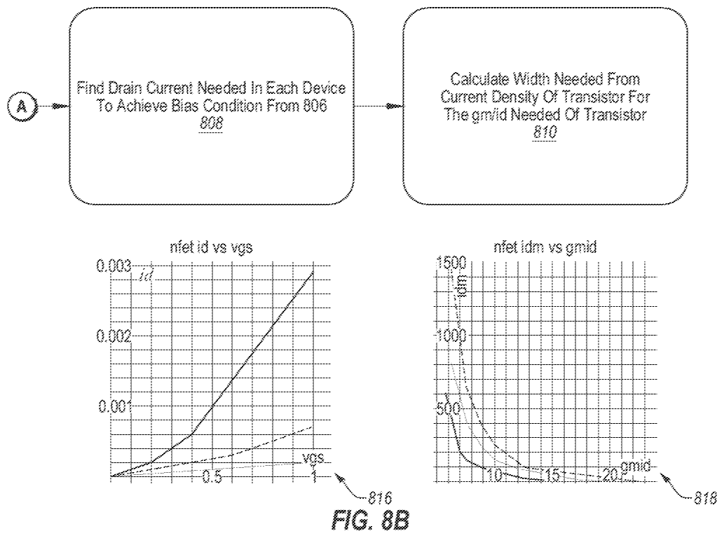

FIGS. 8A and 8B collectively depict an example flowchart of a method 800 related to design migration, and a number of associated plots, according to various embodiments of the disclosure. More specifically, FIGS. 8A and 8B depict a methodology for gm/id migration, and graphical representations of a number of foundry processes demonstrating the migration. Migration may begin with determining a reference process, where a desired design or transistor already exists, and a target process, where the design will be migrated to. Further, simulations may be performed in the reference process to determine bias conditions. For example, as shown in block 802, DC operating point simulations of a given circuit topology may be run to determine bias conditions of each transistor in the topology. For example, bias conditions may include: transconductance of each device (e.g., transistor) in the design, drain to source currents of each device (e.g., transistor) in the design, the intrinsic capacitances of each device (e.g., transistor) in the design, and biasing voltages of each attribute in the device. Bias conditions may be determined for many devices (e.g., transistors) of various lengths and widths.

Continuing with method 800, migration may include determining an inversion region of the devices (e.g., each transistor) to determine the gm/Id of a target process, and capturing the difference, for each transistor, in gm/Id between the reference process and the target process. For example, as shown in block 804, the difference for a transistor may be determined by comparing gm/Id multiplied by the transit frequency of the transistor with the gm/Id of the transistor for different lengths of transistors within a technology node. Plot 812 illustrates transit frequency (“gmidft”) as a function of gm/Id for several example transistors. It is noted that the transistors referenced in relation to method 800 may include NMOS transistors as an example, however, the same principles and processes may apply with regard to other transistors, such as PMOS transistors.

Continuing with method 800, as shown in block 806, migration may also include determining the bias condition for each transistor in the target process for a given gm/Id (e.g., as determined in block 804). For example, determining a bias condition of a transistor may include a sweep of the reference process gate voltage of the transistor to determine gm/Id. Plot 814 illustrates gm/Id as a function of gate-to-source voltage (vgs) for several example NMOS transistors.

Continuing with method 800, as shown in block 808, migration may also include determining the drain current (i.e., of each transistor) necessary to achieve the previously determined bias condition. For example, determining the drain current of a transistor may include a sweep of the gate voltage of the transistor to determine the drain current. Plot 816 illustrates drain current in a transistor (“nfet id”) as a function of vgs for several example NMOS transistors.

Continuing with method 800, as shown in block 810, migration may also include determining a width of each of the transistors based on the gm/Id and the determined current density for the transistors. For example, determining a width of a transistor may include a sweep of the transistor's gm/Id to determine the necessary current density. Plot 818 illustrates current density (“iden”) in units of Amperes per meter (“A/m”) for several example NMOS transistors.

In some embodiments, migration may also include normalizing bias voltages or power supply voltages. Because voltage operating points may be different between processes, bias parameters such as the gate to source voltage or the power supply may be normalized. Normalized bias voltages may range from 0 to 1 instead of the process bias voltages to directly compare operating condition ratios.

Migrating a design using embodiments of the disclosure may be an alternative to manually generating a design in each new process, which is time-consuming and will not yield the same electrical characteristics without significant design time and iteration. Migrating a design by a methodology such as gm/Id provides designs that are electrically functional and close in performance to the source design. Using a migration methodology is also less prone to errors or variations than traditional manual recreations or new designs.

Some embodiments may analyze a circuit design and characterize the circuit. For example, some embodiments may generate a text file of all elements in a circuit using a hierarchy structure, defining all circuits and test devices (e.g., a netlist) of a circuit design. The netlist may be based on various netlist templates, e.g., process-specific templates and/or design-specific templates. Process-specific-netlist aspects may include parameters specific to a process (e.g., a variable for power supply voltage). Design-specific-netlist aspects may include parameters specific to a cell type (e.g., a testbench to test a latch will have different switches and stimuli than is necessary to test an opamp). The design may have been ported from a different transistor technology size or designed in the current process.

The design (or a circuit of the design) may further be characterized. To characterize the design (or the circuit) a series of tests may be run using a testing tool (e.g., a netlist testbench). Tests may include transient, AC, DC, noise, and other types of tests. Simulations provide key Figures Of Merit to indicate the functionality of the design and/or may provide information to a designer to make an informed decision to select one device over another.

A datasheet may be generated. The datasheet may include figures. Additionally or alternatively, various simulation models may also be created.

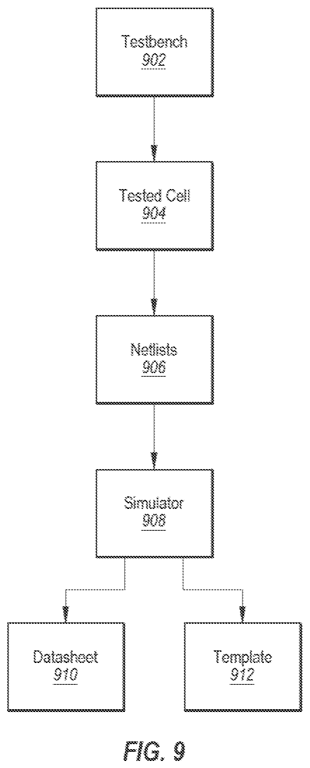

FIG. 9 is a functional block diagram of an example system 900 according to various embodiments of the disclosure. System 900 includes a testbench 902, a tested cell 904, netlists 906, a simulator 908, a datasheet 910, and a template 912.

Testbench 902 may generate a netlist for a number of different cell types. Each netlist may be used to test any variation of the respective cell type. For example, a netlist may be generated for a latch circuit. The netlist may be used to test any variation of latch circuit. Variations of a cell type can include variations in technology size and/or process.

Tested cell 904 is an example of a cell that has been tested, e.g., at testbench 902. Tested cell 904 may include a netlist for a specific circuit, which may be or may include a variant of a cell type. Tested cell 904 may have been designed in the current technology process, or tested cell 904 may have been ported from a different process.

Netlists 906 includes multiple netlists related to tested cell 904. Netlists 906 include netlists that are applicable to multiple different cells (e.g., multiple different cells that are of the cell type of tested cell 904). Additionally or alternatively, netlists 906 includes netlists that are applicable to multiple different processes. Additionally or alternatively, netlists 906 includes netlists that are applicable to tested cell 904 and a process of tested cell 904.

At simulator 908 a number of simulations are performed with regard to netlists 906, e.g., circuits of netlists 906 are simulated. The circuits may be simulated according to various parameters and/or settings. The parameters and/or settings may be related to technology sizes and/or processes. Results of simulations (e.g., corner simulations and/or Monte Carlo simulations) may be saved, e.g., for analysis.

Simulator 908 may generate datasheet 910. Datasheet 910 may describe tested cell 904, for example, datasheet 910 may describe functionality of tested cell 904. Datasheet 910 may be in any suitable format, e.g., text. Datasheet 910 may include simulation results and/or may be based at least in part on simulation results. Datasheet 910 may also include generated plots, e.g., illustrating results of simulations.

For example, a description (e.g., a textual description) of the circuit may be generated (e.g., based on the simulated operations of the circuit). In some examples, the description may include an image representative of the circuit.

Some embodiments may generate layouts from parameterized cells. A topology of a layout may be such that a layout may be generated from a schematic view that follows a methodology of radiation-hardened (RAD-HARD) migration. A RAD-HARD layout may be generated from the schematic view according to the topology of the layout. The topology of the layout may be consistent across transistor technology sizes.

Additionally or alternatively, a RAD-HARD layout can be generated with the same structure that also follows technology size best-practices. A new layout can follow RAD-HARD best-practices, or an existing layout can be modified to follow those same best practices. Examples of RAD-HARD practices include Triple Modular Redundancy (TMR) for digital logic cells or inserting guard ring cells on analog cell blocks.

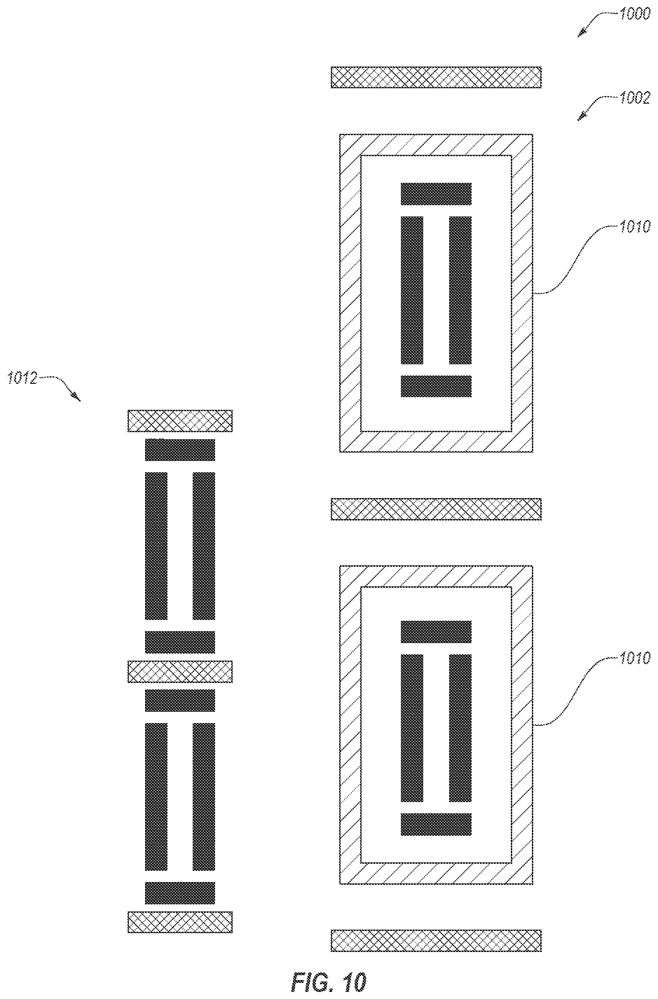

Additionally, a design may maintain layout best-practices in migration (e.g., a differential pair set of transistors can have its appropriate layout migrated or modified for RAD-HARD best practices). As an example, an inverter layout that follows RAD-HARD best practices can be generated from a layout that did not have RAD-HARD in mind. For example, FIG. 10 is a representation of an example FinFet layout 1000 of an inverter 1002 with guard rings 1010 generated from a layout 1012 without guard rings. Inverter 1002 includes gate 1020, source/drain 1022, and power/ground 1024. In one example, the gate/source/drain could be in layout metal1, the power/ground in metal2, and the guard ring in metal 1. It is noted that while the devices get larger from the guard ring, the floorplan of the devices may remain substantially the same.

In accordance with common practice, the various features illustrated in the drawings may not be drawn to scale. The illustrations presented in the disclosure are not meant to be actual views of any particular apparatus (e.g., device, system, etc.) or method, but are merely idealized representations that are employed to describe various embodiments of the disclosure. Accordingly, the dimensions of the various features may be arbitrarily expanded or reduced for clarity. In addition, some of the drawings may be simplified for clarity. Thus, the drawings may not depict all of the components of a given apparatus (e.g., device) or all operations of a particular method.

Terms used herein and especially in the appended claims (e.g., bodies of the appended claims) are generally intended as “open” terms (e.g., the term “including” should be interpreted as “including, but not limited to,” the term “having” should be interpreted as “having at least,” the term “includes” should be interpreted as “includes, but is not limited to,” etc.).

Additionally, if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to embodiments containing only one such recitation, even when the same claim includes the introductory phrases “one or more” or “at least one” and indefinite articles such as “a” or “an” (e.g., “a” and/or “an” should be interpreted to mean “at least one” or “one or more”); the same holds true for the use of definite articles used to introduce claim recitations. As used herein, “and/or” includes any and all combinations of one or more of the associated listed items.

In addition, even if a specific number of an introduced claim recitation is explicitly recited, it is understood that such recitation should be interpreted to mean at least the recited number (e.g., the bare recitation of “two recitations,” without other modifiers, means at least two recitations, or two or more recitations). Furthermore, in those instances where a convention analogous to “at least one of A, B, and C, etc.” or “one or more of A, B, and C, etc.” is used, in general such a construction is intended to include A alone, B alone, C alone, A and B together, A and C together, B and C together, or A, B, and C together, etc. For example, the use of the term “and/or” is intended to be construed in this manner.

Further, any disjunctive word or phrase presenting two or more alternative terms, whether in the description, claims, or drawings, should be understood to contemplate the possibilities of including one of the terms, either of the terms, or both terms. For example, the phrase “A or B” should be understood to include the possibilities of “A” or “B” or “A and B.”

Additionally, the use of the terms “first,” “second,” “third,” etc., are not necessarily used herein to connote a specific order or number of elements. Generally, the terms “first,” “second,” “third,” etc., are used to distinguish between different elements as generic identifiers. Absence a showing that the terms “first,” “second,” “third,” etc., connote a specific order, these terms should not be understood to connote a specific order. Furthermore, absence a showing that the terms “first,” “second,” “third,” etc., connote a specific number of elements, these terms should not be understood to connote a specific number of elements.

As used herein, the term “substantially” in reference to a given parameter, property, or condition means and includes to a degree that one of ordinary skill in the art would understand that the given parameter, property, or condition is met with a small degree of variance, such as, for example, within acceptable manufacturing tolerances. By way of example, depending on the particular parameter, property, or condition that is substantially met, the parameter, property, or condition may be at least 90% met, at least 95% met, or even at least 99% met.

The embodiments of the disclosure described above and illustrated in the accompanying drawings do not limit the scope of the disclosure, which is encompassed by the scope of the appended claims and their legal equivalents. Any equivalent embodiments are within the scope of this disclosure. Indeed, various modifications of the disclosure, in addition to those shown and described herein, such as alternative useful combinations of the elements described, will become apparent to those skilled in the art from the description. Such modifications and embodiments also fall within the scope of the appended claims and equivalents.

What is claimed is:

1. A method of generating an integrated circuit design, the method comprising:
generating a contextual cell including a super-master and defining at least one sub-master, the at least one sub-master derived from parameterized values and a context of an instance of the super-master.

2. The method of claim 1, further comprising generating the at least one sub-master based at least in part on components of cells proximate the contextual cell.

3. The method of claim 2, further comprising identifying the components including other instances and shapes based on a location of the instance.

4. The method of claim 1, further comprising accessing an internal structure of the contextual cell and at least one proximate cell.

5. The method of claim 4, further comprising identifying features of the internal structure of the contextual cell and of one or more proximate cells to generate the at least one sub-master derived from a set of identified features and prescribed rule-sets.

6. The method of claim 1, wherein features from one or more proximate cells are used in creation of the at least one sub-master.

7. The method of claim 1, further comprising generating a layout of the contextual cell via radiation hardening including performing Triple Modular Redundancy (TMR) for digital logic cells, inserting guard ring cells on analog cell blocks, or both.

8. A method of generating an integrated circuit design, the method comprising:
generating an instance of a contextual cell, the contextual cell comprising:
a definition;
a structure generator configured to:
access an internal structure of at least one cell proximate to a location of the contextual cell; and
generate an internal structure of the instance of the contextual cell based on the definition and the internal structure of the at least one cell;
a super-master; and
at least one sub-master.

9. The method of claim 8, further comprising generating a layout of the contextual cell via performing radiation hardening including performing Triple Modular Redundancy (TMR) for digital logic cells, inserting guard ring cells on analog cell blocks, or both.

10. A method of migrating from a source technology to a destination technology, the method comprising:
simulating a circuit including a number of components arranged according to a topology to determine bias conditions of the circuit;
determining an inversion region of each of the number of components;
comparing transconductance by drain to source current (gm/Ids) for inversion regions of the number of components according to a source technology to gm/Ids for inversion regions of the number of components according to a destination technology;
determining, for each component of the number of components, gm/Ids according to the destination technology;
determining bias conditions for each determined gm/Ids of the number of components according to the destination technology;
determining drain currents for each component of the number of components to achieve the respective determined bias conditions; and
determining a width of each component according to the destination technology responsive to the determined drain currents.

11. The method of claim 10, wherein simulating the circuit including the number of components comprises simulating the circuit including a number of transistors.

12. The method of claim 10, wherein simulating the circuit comprises performing DC operating point simulations on the circuit to determine the bias conditions of the circuit.

13. The method of claim 10, wherein determining respective inversion regions of the number of components comprises determining respective inversion regions of a number of transistors responsive to one or more of transconductance by drain current (“gm/Id”), respective transit frequencies of the number of transistors, or respective gm/Ids of the number of transistors.

14. A method, comprising:
obtaining a cell of a cell type;
generating one or more netlists representative of the cell type;
simulating, based on the one or more netlists, operations of a circuit of the cell; and
generating a textual description of the circuit based on the simulated operations of the circuit.

15. The method of claim 14, wherein generating the textual description comprises generating an image representative of the circuit.

16. The method of claim 14, wherein the simulating comprises simulating operations of the circuit across one or more of size variations of the cell or process variations of the cell.

17. A method of performing device migration from a reference process to a target process, the method comprising:
performing DC operating point simulations to determine bias conditions of each transistor of a number of transistors in a circuit of a reference process;
determining an inversion region of each transistor of the number of transistors to determine a transconductance by drain current (gm/Id) of a target process;
determining, for each transistor of the number of transistors, a difference in gm/Id between the reference process and the target process;
determining a bias condition for each transistor of the number of transistors in the target process;
determining, for each transistor of the number of transistors, a drain current necessary to achieve the determined bias conditions of the target process; and
determining a width of each transistor of the number of transistors based at least partially on the determined drain current of the transistor.

18. The method of claim 17, wherein performing DC operating point simulations to determine the bias conditions of each transistor of the number of transistors comprises performing DC operating point simulations to determine one or more of a transconductance of each transistor of the number of transistors, a drain to source current of each transistor of the number of transistors, an intrinsic capacitance of each transistor of the number of transistors, or a biasing voltage of each transistor of the number of transistors.

19. The method of claim 17, wherein determining the difference in gm/Id between the reference process and the target process comprises comparing, for each transistor of the number of transistors, a gm/Id multiplied by a transit frequency of each transistor of the number of transistors with the gm/Id of each transistor of the number of transistors for different lengths of transistors within a technology node.

20. The method of claim 17, wherein determining, for each transistor of the number of transistors, the drain current comprises performing a sweep of a gate voltage of each transistor of the number of transistors to the drain current for each transistor of the number of transistors.
